(19) United States
(12) Patent Application Publication
(10) Pub. No.: US 2008/0142879 A1
(43) Pub. Date: Jun. 19, 2008

(54) INTEGRATED CIRCUIT SYSTEM EMPLOYING DIFFERENTIAL SPACERS

(75) Inventors: Yung Fu Chong, Singapore (SG); Jae Gon Lee, Singapore (SG)

Correspondence Address: LAW OFFICES OF MIKIO ISHIMARU, 333 W. EL CAMINO REAL, SUITE 330, SUNNYVALE, CA, 94087, US

(73) Assignee: CHARTERED SEMICONDUCTOR MANUFACTURING LTD., Singapore (SG)

(21) Appl. No.: 11/611,126

(22) Filed: Dec. 14, 2006

(51) Int. Cl. H01L 29/76

(52) U.S. Cl. 257/327

(57) ABSTRACT

An integrated circuit system that includes: providing a substrate with an NFET device and a PFET device; forming an NFET first liner and an NFET first spacer over the NFET device; forming a PFET first liner and a PFET first spacer over the PFET device; forming a punch-through suppression layer within a PFET source/drain; forming an NFET differential spacer; and forming a PFET differential spacer.

### CROSS-REFERENCE TO RELATED APPLICATION(S)

The present application contains subject matter related to a co-pending U.S. Patent Application by Jae Gon Lee, Lee Wee Teo, and Seong-Dong Kim, entitled “Integrated Circuit System Employing Strained Technology”. The related application is assigned to Chartered Semiconductor Manufacturing Ltd. and is identified by docket number ICIS-0522.

### TECHNICAL FIELD

The present invention relates generally to integrated circuits, and more particularly to an integrated circuit system employing differential spacers.

### BACKGROUND ART

A conventional metal-oxide-semiconductor field-effect transistor (MOSFET) generally includes a semiconductor substrate, having a source, a drain, and a channel located between the source and drain. A gate stack composed of a conductive material (i.e.—a gate) and an oxide layer (i.e.—a gate oxide) are typically located directly above the channel. During operation, an inversion layer forms a conducting bridge or “channel” between the source and drain when a voltage is applied to the gate. Both p-channel and n-channel MOSFET technologies are available and can be combined on a single substrate in one technology, called complementary-metal-oxide-semiconductor or CMOS. This conventional MOSFET design (both p-channel and n-channel) finds application in many of today's consumer electronics, such as cellphones, video cameras, portable music players, computers, etc.

Scaling of the MOSFET, whether by itself or in a CMOS configuration, has become a major challenge for the semiconductor industry. Size reduction of the integral parts of a MOSFET has lead to improvements in device operation speed and packing density, but size reduction has its limits. For example, as scaling of the MOSFET reaches the submicron era, intended and unintended strain effects can become a design problem. Consequently, new methods must be developed to maintain the expected device performance enhancement from one generation of devices to the next.

Generally, the amount of current that flows through the channel of a transistor is directly proportional to the mobility of carriers within the channel region. Consequently, the higher the mobility of the carriers in the transistor channel, the more current that can flow through the device and the faster it can operate. One way to increase the mobility of carriers in the channel of a transistor is to manufacture the transistor with a strained channel. Depending upon the type of strained channel, significant carrier mobility enhancement has been reported for both electrons and holes. Commonly, a compressively strained channel exhibits enhanced hole mobility and a tensile strained channel exhibits enhanced electron mobility.

Conventional techniques employed to affect strain within the channel region of a MOSFET may include: forming shallow trench isolation structures or depositing etch stop layers. Each of these techniques can be engineered to promote appropriate mechanical strain within the channel region. Unfortunately, some conventional MOSFET formation techniques can degrade device performance. For example, a reduced resistance silicide electrical contact formed over a source/drain region may produce a disadvantageous strain within a channel, thereby degrading device performance. Furthermore, some conventional processing steps may displace a strain inducing layer too far from a channel region, thereby reducing its efficacy for promoting carrier mobility.

Thus, a need still remains for a reliable integrated circuit system and method of fabrication, wherein the integrated circuit system exhibits improved carrier mobility due to the controlled application of stress to the channel. In view of the ever-increasing commercial competitive pressures, increasing consumer expectations, and diminishing opportunities for meaningful product differentiation in the marketplace, it is increasingly critical that answers be found to these problems. Moreover, the ever-increasing need to save costs, improve efficiencies, and meet such competitive pressures adds even greater urgency to the critical necessity that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including: providing a substrate with an NFET device and a PFET device; forming an NFET first liner and an NFET first spacer over the NFET device; forming a PFET first liner and a PFET first spacer over the PFET device; forming a punch-through suppression layer within a PFET source/drain; forming an NFET differential spacer; and forming a PFET differential spacer.

Certain embodiments of the invention have other advantages in addition to or in place of those mentioned above. The advantages will become apparent to those skilled in the art from a reading of the following detailed description when taken with reference to the accompanying drawings.

### BRIEF DESCRIPTION OF THE DRAWINGS

FIG. 1 is a cross sectional view of an integrated circuit system in an initial stage of manufacture in accordance with an embodiment of the present invention

FIG. 2 is the structure of FIG. 1 after the formation of a protective layer and a first mask;

FIG. 3 is the structure of FIG. 2 after removal of a first mask;

FIG. 4 is the structure of FIG. 3 after formation of a PFET recess in a substrate;

FIG. 5 is the structure of FIG. 4 after formation of a punch-through suppression layer within a PFET source/drain;

FIG. 6 is the structure of FIG. 5 after further processing;

FIG. 7 is the structure of FIG. 6 after formation of an NFET second liner, a PFET second liner, an NFET second spacer, and a PFET second spacer;

FIG. 8 is the structure of FIG. 7 after removal of an NFET second spacer;

FIG. 9 is the structure of FIG. 8 after removal of an NFET second liner and formation of an NFET source/drain;

FIG. 10 is the structure of FIG. 9 after further processing;

FIG. 11 is a flow chart of an integrated circuit system for an integrated circuit system in accordance with an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown exaggerated in the drawing FIGS. Additionally, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane. The term “processing” as used herein includes deposition of material or photoresist, patterning, exposure, development, etching, cleaning, and/or removal of the material or photoresist as required in forming a described structure.

Generally, the present invention manipulates the stresses created within a channel to maximize the performance of both NFET (n-channel Field-Effect-Transistor) and PFET (p-channel Field-Effect-Transistor) configurations through the use of differential spacers. The present inventors have found that strain engineered differential spacer design can maximize PFET performance by displacing a silicide electrical contact away from the PFET channel, where the silicide electrical contact reduces the net stress on the PFET channel, while preserving NFET performance by maintaining the proximity effect of a tensile stressed dielectric layer.

Although the present invention will discuss a first spacer design versus a first spacer and a second spacer design, it is not to be limited to such a narrow construction. The present invention more accurately encompasses a differential spacer design that is not distinguished by the number of spacers, but by the overall spacer thickness and its desired effect upon its intended target. For example, the present invention may discuss an NFET configuration with only a first spacer design, but may encompass an NFET configuration with more than one spacer, so long as the overall spacer thickness does not detrimentally alter the proximity effect of a subsequently deposited tensile dielectric layer. Furthermore, by way of example, the present invention may discuss a PFET configuration with a first spacer and a second spacer, but may encompass a PFET configuration with a single spacer design or a design with more than two spacers, wherein the overall PFET spacer thickness has been optimized to negate the detrimental effects of the low resistivity contact adjacent the PFET channel.

The following figures generally illustrate by way of example and not by limitation, an exemplary process for forming an integrated circuit system 100, and they are not to be construed as limiting.

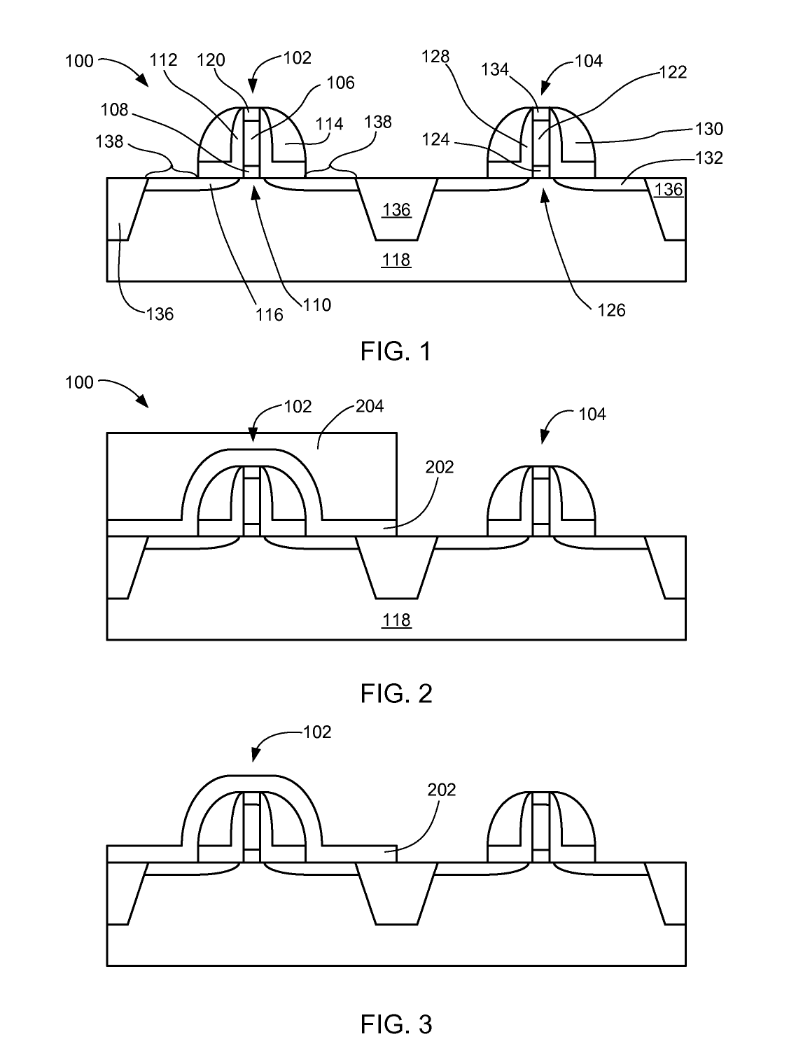

Referring now to FIG. 1, therein is shown a cross sectional view of the integrated circuit system 100 in an initial stage of manufacture in accordance with an embodiment of the present invention. The integrated circuit system 100 can be formed from conventional deposition, patterning, photolithography, and etching to form an NFET device 102 and a PFET device 104. The NFET device 102 and the PFET device 104 may operate together, thereby forming a complementary metal-oxide-semiconductor (CMOS) configuration.

The NFET device 102 includes an NFET gate 106. Below the NFET gate 106 is an NFET gate oxide 108, and below the NFET gate oxide 108 is an NFET channel 110. Surrounding the NFET gate 106 is an NFET first liner 112, and surrounding the NFET first liner 112 is an NFET first spacer 114. By way of example, the NFET first liner 112 may be made from a material that includes oxygen and the NFET first spacer 114 may be made from a material that includes nitrogen. An NFET source/drain extension 116, formed by a low to medium-dose implant, extends from the NFET channel 110 in a substrate 118 to facilitate dimensional reductions for the scaling of the integrated circuit system 100. An NFET cap 120, such as a nitride or an oxynitride cap, helps to protect the NFET gate 106 during subsequent processing steps.

The PFET device 104 includes a PFET gate 122. Below the PFET gate 122 is a PFET gate oxide 124, and below the PFET gate oxide 124 is a PFET channel 126. Surrounding the PFET gate 122 is a PFET first liner 128, and surrounding the PFET first liner 128 is a PFET first spacer 130. By way of example, the PFET first liner 128 may be made from a material that includes oxygen and the PFET first spacer 130 may be made from a material that includes nitrogen. A PFET source/drain extension 132, formed by a low to medium-dose implant, extends from the PFET channel 126 in the substrate 118 to facilitate dimensional reductions for the scaling of the integrated circuit system 100. A PFET cap 134, such as a nitride or an oxynitride cap, helps to protect the PFET gate 122 during subsequent processing steps.

As is known within the art, the NFET gate 106 and the PFET gate 122 may include any type of conducting material, such as silicon, polysilicon, and/or metal and the NFET gate oxide 108 and the PFET gate oxide 124 may include high-K dielectric constant materials and low-K dielectric constant materials.

An isolation structure 136, such as a shallow trench isolation and/or a field oxide is formed within or on the substrate 118. Furthermore, the substrate 118 may optionally include a strain suppressing feature 138 adjacent the NFET device 102. Generally, the strain suppressing feature 138 is rectangular and parallel to the length of the NFET gate 106. The strain suppressing feature 138 helps to control detrimental strain generated by the isolation structure 136 upon the NFET device 102. Thus, the detrimental strain generated by the isolation structure 136 upon the NFET device 102 can be controlled, adjusted to a predetermined level, and optimized by strategically positioning the strain suppressing feature 138.

For purposes of illustration, the substrate 118 may include semiconductor materials selected from silicon (Si) and/or Germanium (Ge). Furthermore, by way of example, the substrate 118 may include a bulk semiconductor substrate or a silicon-on-insulator substrate.

Referring now to FIG. 2, therein is shown the structure of FIG. 1 after the formation of a protective layer 202 and a first mask 204. The protective layer 202, which may include a low temperature oxide layer, is deposited over the integrated circuit system 100. However, it is to be understood that the composition of the protective layer 202 is not critical, what is important is that the protective layer 202 be made from a material that protects the NFET device 102 from damage during subsequent etching of the substrate 118 and/or be made from a material that helps to block the deposition of a subsequent layer, such as a silicon germanium layer.

The first mask 204 is formed over the NFET device 102. The first mask 204 shields the protective layer 202 formed over the NFET device 102 from a subsequent etch step, which removes the protective layer 202 from over the PFET device 104. By way of example, the subsequent etch step may include an oxide wet etch, if the protective layer 202 includes an oxide material. The materials and techniques used to form the first mask 204 are well know in the art and not repeated herein.

Referring now to FIG. 3, therein is shown the structure of FIG. 2 after removal of the first mask 204, of FIG. 2. The first mask 204 is removed from over the NFET device 102, exposing the protective layer 202 formed over the NFET device 102. For purposes of illustration, the first mask 204 may be removed by a plasma or a wet resist strip process.

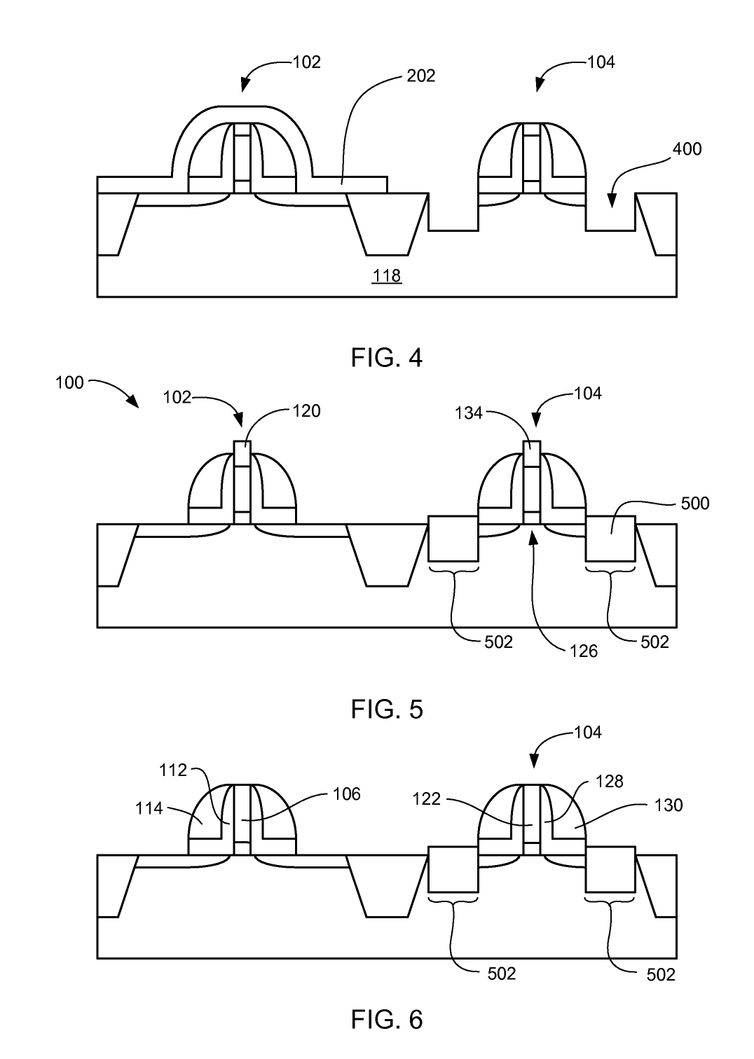

Referring now to FIG. 4, therein is shown the structure of FIG. 3 after formation of a PFET recess 400 in the substrate 118. The PFET recess 400 can be formed by selectively etching portions of the substrate 118 adjacent the PFET device 104. The PFET recess 400 can be formed to a depth of about 150 angstroms to about 1600 angstroms. By way of example, if the substrate 118 is made from silicon, the etching process for forming the PFET recess 400 may employ reactive ion etching or other processes that are highly selective to silicon.

After the etching process, a wet clean step may be employed to remove any residual surface contaminants, such as particles, organics and native oxides. Optionally, the clean step can be in the gaseous form, with mixtures of gases that include HF. The protective layer 202 shields the NFET device 102 from this etching process.

Referring now to FIG. 5, therein is shown the structure of FIG. 4 after formation of a punch-through suppression layer 500 within a PFET source/drain 502. By way of example, the punch-through suppression layer 500 can be formed within the PFET recess 400, of FIG. 4, after an epitaxial pre-clean process. The punch-through suppression layer 500 helps to prevent the PFET channel 126 from shorting and causing an undesirable leakage current, which can lead to failure of the integrated circuit system 100. Channel shorting commonly occurs when the drain field extends too far into the channel region and contacts the source, thereby causing punch-through of the majority carriers.

It has been discovered by the present inventors that this channel shorting phenomena can be ameliorated by forming the punch-through suppression layer 500 within the PFET source/drain 502. Generally, the present inventors have discovered that the proximity effect of the punch-through suppression layer 500 can be enhanced by tailoring the PFET source/drain 502 configuration to suppress short channel effects. As is evident from disclosure herein, short channel effects can be minimized by forming the PFET source/drain 502 in a step-shaped configuration.

However, it is to be understood that the PFET source/drain 502 is not to be limited to a particular configuration or depth. In accordance with the present invention, the PFET source/drain 502 may include any configuration and/or depth profile that reduces short channel effects.

Notably, the punch-through suppression layer 500 may also introduce strain within the PFET channel 126, thereby improving the performance of the PFET device 104. It will be appreciated by those skilled in the art that an appropriately applied strain to the channel region of a transistor device may enhance the amount of current that can flow through the device.

By way of example, the present invention may employ the punch-through suppression layer 500 made from materials including silicon germanium, or more specifically, in-situ p-type doped epitaxially grown silicon germanium, to induce strain within the PFET channel 126. By way of example, if the punch-through suppression layer 500 includes a silicon germanium layer then the germanium concentration of the punch-through suppression layer 500 may vary between about 5 to about 45 atomic percent. However it is to be understood that the punch-through suppression layer 500 is not to be limited to any particular type of material. In accordance with the present invention, the punch-through suppression layer 500 may include any material that is engineered to induce strain and suppress short channel effects within the PFET channel 126.

Furthermore, the thickness of the punch-through suppression layer 500 deposited may include any thickness that appropriately alters the strain and/or suppresses the short channel effects within the PFET channel 126.

During deposition of the punch-through suppression layer 500, the protective layer 202, of FIG. 4, may remain over the NFET device 102 to help protect the NFET device 102. After deposition of the punch-through suppression layer 500 the protective layer 202 can be removed. For purposes of illustration, the protective layer 202 can be removed by an oxide etch process. Depending upon the material of the protective layer 202, a portion of the NFET cap 120 and a portion of the PFET cap 134 can be exposed concurrently while etching the protective layer 202 or a portion of the NFET cap 120 and a portion of the PFET cap 134 can be exposed by a subsequent etch process.

Referring now to FIG. 6, therein is shown the structure of FIG. 5 after further processing. The NFET cap 120, of FIG. 5, and the PFET cap 134, of FIG. 5, have been removed from over the NFET gate 106 and the PFET gate 122, respectively. Depending upon the materials chosen for the NFET cap 120, the NFET first liner 112, the NFET first spacer 114, the PFET cap 134, the PFET first liner 128, and the PFET first spacer 130, an anisotropic reactive ion etch with a high selectivity of nitride to oxide can be employed to remove the NFET cap 120 and the PFET cap 134. By way of example, an anisotropic reactive ion etch with a high selectivity of nitride to oxide can be employed if the NFET cap 120, the NFET first spacer 114, the PFET cap 134, and the PFET first spacer 130 include nitrogen and the NFET first liner 112 and the PFET first liner 128 include oxygen.

An optional additional p-type dopant implant into the PFET device 104 can be performed to appropriately adjust the PFET source/drain 502 concentration. The p-type dopant may include boron, for example.

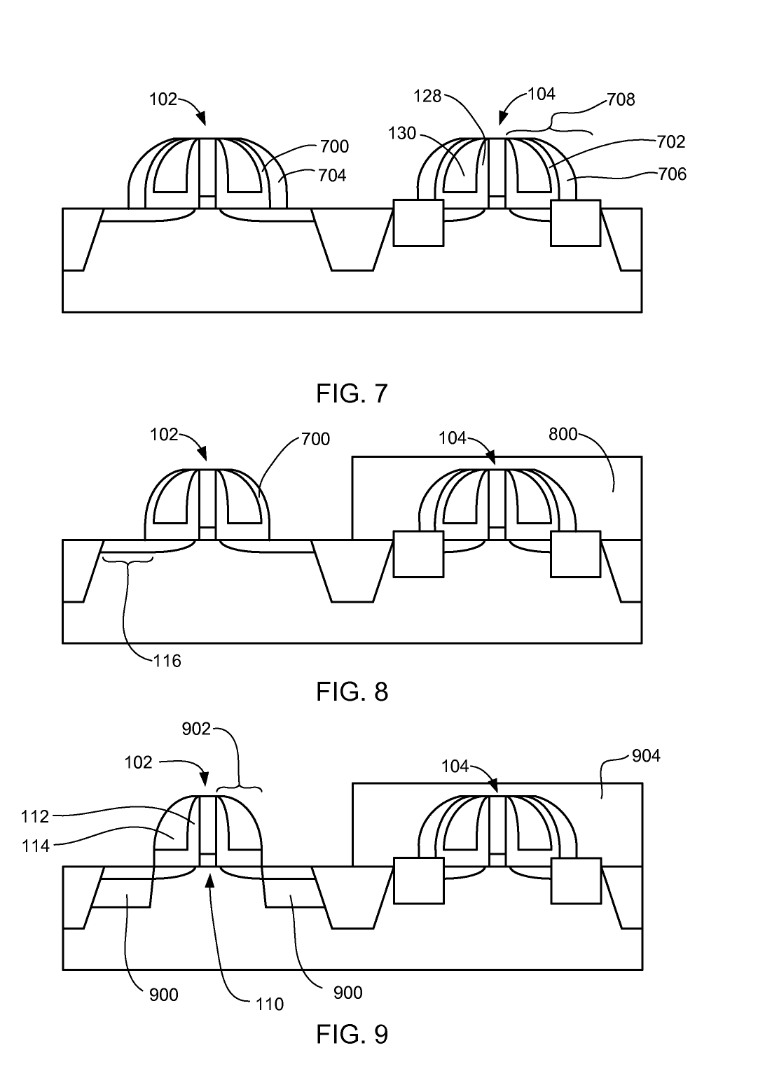

Referring now to FIG. 7, therein is shown the structure of FIG. 6 after formation of NFET second liner 700, a PFET second liner 702, an NFET second spacer 704, and a PFET second spacer 706. During this process step the NFET second liner 700 and the PFET second liner 702 are deposited over the NFET device 102 and the PFET device 104, respectively. By way of example, the NFET second liner 700 and the PFET second liner 702 can be formed by blanket deposition followed by a subsequent etch back before or after the NFET second spacer 704 and the PFET second spacer 706 are deposited, or by selective deposition.

Additionally, the NFET second spacer 704 and the PFET second spacer 706 are deposited over the NFET second liner 700 and the PFET second liner 702, respectively. By way of example, the NFET second spacer 704 and the PFET second spacer 706 can be formed by blanket deposition followed by etch back, or by selective deposition.

After deposition of the PFET second liner 702 and the PFET second spacer 706, the PFET first liner 128, the PFET first spacer 130, the PFET second liner 702 and the PFET second spacer 706 can collectively be referred to as a PFET differential spacer 708.

As an exemplary illustration, the NFET second liner 700 and the PFET second liner 702 may include a dielectric material, such as a low temperature oxide deposited material, and the NFET second spacer 704 and the PFET second spacer 706 may include a dielectric material, such as a nitride.

Etching processes, such as a reactive ion etch, can be employed to configure the NFET second spacer 704, the NFET second liner 700, the PFET second spacer 706 and the PFET second liner 702 as desired.

Referring now to FIG. 8, therein is shown the structure of FIG. 7 after removal of the NFET second spacer 704, of FIG.7. A second mask 800 is formed over the PFET device 104. The second mask 800 shields the PFET device 104 from the subsequent etch removal of the NFET second spacer 704 from over the NFET device 102, or more specifically, from over the NFET second liner 700. Depending upon the material chosen for the NFET second spacer 704, the etch process employed to remove the NFET second spacer 704 may include a nitride isotropic reactive ion etch or a chemical dry etching technique. The materials and techniques used to form the second mask 800 are well know in the art and not repeated herein.

Referring now to FIG. 9, therein is shown the structure of FIG. 8 after removal of the NFET second liner 700, of FIG. 8, and formation of an NFET source/drain 900. The second mask 800, of FIG. 8, is removed from over the PFET device 104. As an exemplary illustration, the second mask 800 may be removed by a plasma or a wet resist strip process. The NFET second liner 700 is removed from over the NFET device 102. Depending upon the composition of the NFET second liner 700, an oxide deglaze may also be performed.

After removal of the NFET second liner 700 and the NFET second spacer 704, of FIG. 7, the NFET first liner 112 and the NFET first spacer 114 can collectively be referred to as a NFET differential spacer 902. It can be appreciated by those skilled in the art that the size and/or width of the NFET differential spacer 902 can affect the performance of the NFET device 102 due to its ability to offset a subsequently deposited tensile strained dielectric layer from the NFET channel 110. For example, if the size and/or width of the NFET differential spacer 902 is configured incorrectly (i.e.—too large) then the stress transfer from the subsequently deposited tensile strained dielectric layer will be weakened. Notably, the present invention allows the design engineer to configure the size and/or width of the NFET differential spacer 902 to optimize the tensile stress of a subsequently deposited tensile strained dielectric layer upon the NFET channel 110. As an exemplary illustration, the subsequently deposited tensile strained dielectric layer may include a contact etch stop layer, such as a nitride layer.

A third mask 904 is then formed over the PFET device 104. The third mask 904 protects the PFET device 104 from a subsequent source/drain implant step of the NFET source/drain 900. However, it is not mandatory to remove the second mask 800, of FIG. 8, and then reform the third mask 904. The second mask 800 can be used to block the PFET 104 during the subsequent source/drain implant step of the NFET source/drain 900.

The NFET source/drain 900 is formed adjacent the NFET device 102 by, for example, an n-type dopant implantation step. The NFET source/drain 900 is aligned to the NFET first spacer 114, which remains after the removal of the NFET second liner 700.

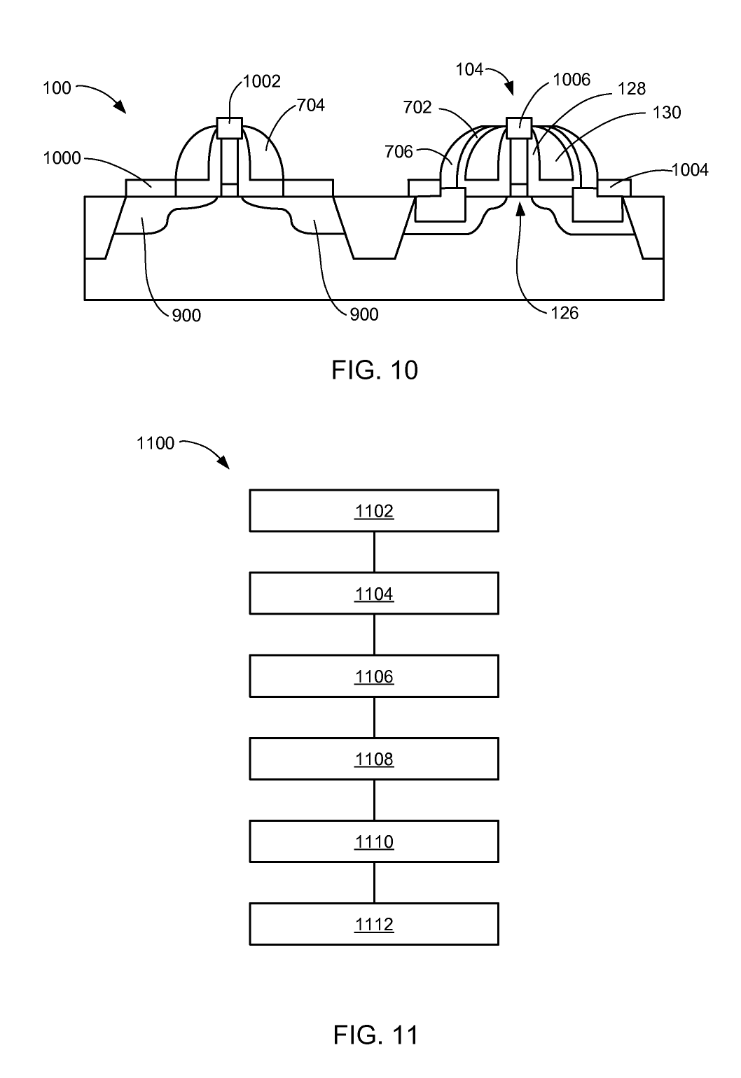

Referring now to FIG. 10, therein is shown the structure of FIG. 9 after further processing. The third mask 904, of FIG. 9, is removed from over the integrated circuit system 100, thereby exposing the NFET device 102 and the PFET device 104 for further processing.

To improve contact formation with the active areas of the integrated circuit system 100, a silicide or salicide process may be employed to form a low resistivity contact, such as, an NFET source/drain silicide contact 1000, an NFET gate silicide contact 1002, a PFET source/drain silicide contact 1004, and a PFET gate silicide contact 1006. It is to be understood that the low resistivity contact may include any conducting compound that forms an electrical interface between itself and another material that is thermally stable and provides uniform electrical properties with low resistance. For purposes of illustration, the low resistivity contact may include refractory metal materials such as, nickel (Ni), cobalt (Co), titanium (Ti), tungsten (W), platinum (Pt), or nickel platinum (NiPt).

It has been discovered by the present inventors that the performance of the PFET device 104 can be affected by the formation of the PFET source/drain silicide contact 1004. The present inventors have discovered that the PFET source/drain silicide contact 1004 can detrimentally affect the PFET device 104 when it is placed too close to the PFET channel 126. While not wanting to be bound by any particular theory, the present inventors believe that the tensile nature of the PFET source/drain silicide contact 1004 can adversely impact hole mobility within the PFET channel 126. The affect of the PFET source/drain silicide contact 1004 is even more pronounced when the PFET device 104 includes embedded silicon germanium source/drain regions.

Notably, the present invention employs the PFET source/drain silicide contact 1004 displaced from the PFET channel 126 by an amount that is equal to the distance occupied by the PFET first liner 128, the PFET first spacer 130, the PFET second liner 702 and the PFET second spacer 706. By displacing the PFET source/drain silicide contact 1004 by this amount form the PFET channel 126, the detrimental proximity effect of the PFET source/drain silicide contact 1004 can be diminished. Accordingly, it is to be understood that the distance or amount of displacement of the PFET source/drain silicide contact 1004 from the PFET channel 126 will depend upon the design engineers desired strategic reduction of the detrimental proximity effect of the PFET source/drain silicide contact 1004 upon the PFET channel 126. Stated another way, the width of each of the PFET first liner 128, the PFET first spacer 130, the PFET second liner 702 and the PFET second spacer 706 can be determined by the desired amount of reduction in the tensile stress upon the PFET channel 126.

For purposes of illustration, the NFET source/drain silicide contact 1000 and the PFET source/drain silicide contact 1004 can be aligned to the NFET second spacer 704 and the PFET second spacer 706, respectively.

After formation of the NFET source/drain silicide contact 1000, the NFET gate silicide contact 1002, the PFET source/drain silicide contact 1004, and the PFET gate silicide contact 1006, conventional processing steps, such as a spike anneal and deposition of dielectric layers engineered to promote compressive/tensile stain can be performed.

Although the present invention depicts formation of the PFET second liner 702 and the PFET second spacer 706 over the PFET device 104 before formation of the NFET source/drain 900, it is to be understood that this sequence is not essential. In accordance with the scope of the present invention, the PFET second liner 702 and the PFET second spacer 706 need only be formed over the PFET device 104 before formation of the PFET source/drain silicide contact 1004 to help prevent the detrimental proximity effect that the PFET source/drain silicide contact 1004 may have upon the PFET channel 126.

Referring now to FIG. 11, therein is shown a flow chart of an integrated circuit system 1100 for the integrated circuit system 100 in accordance with an embodiment of the present invention. The integrated circuit system 1100 includes providing a substrate with an NFET device and a PFET device in a block 1102; forming an NFET first liner and an NFET first spacer over the NFET device in a block 1104; forming a PFET first liner and a PFET first spacer over the PFET device in a block 1106; forming a punch-through suppression layer within a PFET source/drain in a block 1108; forming an NFET differential spacer in a block 1110; and forming a PFET differential spacer in a block 1112.

It has been discovered that the present invention thus has numerous aspects. A principle aspect is that the present invention helps to reduce the detrimental proximity effect of a silicide contact formed over the PFET source/drain region. The present invention achieves this objective by displacing the PFET source/drain silicide contact from the PFET channel by an amount substantially equal to the width of the PFET first liner, the PFET first spacer, the PFET second liner, and the PFET second spacer.

Another aspect of the present invention is that a silicon germanium punch-through suppression layer can induce compressive strain/stress in the PFET channel, and if the PFET source/drain silicide contact is tensile in nature (for example, NiSi) it will reduce the effective stress induced by the SiGe PFET S/D.

Another aspect of the present invention is that it provides an NFET differential spacer configured to increase tensile strain within an NFET channel. The present invention achieves this objective by configuring an NFET differential spacer to allow a tensile strained dielectric layer in close proximity to the NFET channel.

Another aspect of the present invention is that it provides a punch-through suppression layer that helps to suppress short channel effects associated with dimensional scaling of a PFET device by configuring the PFET source/drain to suppress punch-through occurrences.

Yet another aspect of the present invention is that it provides increased strain within the PFET channel by depositing a punch-through suppression layer adjacent the PFET channel. For example, a silicon germanium punch-through suppression layer can induce compressive strain/stress in the PFET channel.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system of the present invention furnishes important and heretofore unknown and unavailable solutions, capabilities, and functional aspects for enhancing NFET and PFET device performance. The resulting processes and configurations are straightforward, cost-effective, uncomplicated, highly versatile and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated circuit system comprising:
providing a substrate with an NFET device and a PFET device;
forming an NFET first liner and an NFET first spacer over the NFET device;
forming a PFET first liner and a PFET first spacer over the PFET device;
forming a punch-through suppression layer within a PFET source/drain;
forming an NFET differential spacer; and
forming a PFET differential spacer.

2. The system as claimed in claim 1 wherein:
forming the NFET differential spacer includes etching an NFET second liner and an NFET second spacer.

3. The system as claimed in claim 1 wherein:
forming the PFET differential spacer includes depositing a PFET second liner and a PFET second spacer.

4. The system as claimed in claim 1 further comprising:
forming a PFET source/drain silicide contact aligned with a PFET second spacer of the PFET differential spacer.

5. The system as claimed in claim 1 further comprising:
configuring the NFET differential spacer such that tensile stresses can be formed within an NFET channel; and
configuring the PFET differential spacer to prevent tensile stresses within a PFET channel.

6. An integrated circuit system comprising:
providing a substrate with an NFET device and a PFET device;
forming an NFET first liner, a PFET first liner, an NFET first spacer, and a PFET first spacer;
forming a PFET recess;
forming a punch-through suppression layer within the PFET recess;
forming an NFET second liner, a PFET second liner, an NFET second spacer, and a PFET second spacer;
removing the NFET second liner and the NFET second spacer;
forming an NFET source/drain;
forming an NFET source/drain silicide contact aligned to the NFET first spacer; and
forming a PFET source/drain silicide contact aligned to the PFET second spacer.

7. The system as claimed in claim 6 wherein:
forming the punch-through suppression layer includes forming a silicon germanium layer.

8. The system as claimed in claim 6 wherein:
forming the NFET source/drain silicide contact and the PFET source/drain silicide contact includes depositing materials selected from refractory metals.

9. The system as claimed in claim 6 further comprising:
forming the NFET first liner, the PFET first liner, the NFET second liner, and the PFET second liner from a material that includes oxygen.

10. The system as claimed in claim 6 further comprising:
forming the NFET first spacer, the PFET first spacer, the NFET second spacer, and the PFET second spacer from a material that includes nitrogen.

11. An integrated circuit system comprising:
a substrate with an NFET device and a PFET device;
an NFET first liner and an NFET first spacer over the NFET device;
a PFET first liner and a PFET first spacer over the PFET device;
a punch-through suppression layer within a PFET source/drain;
an NFET differential spacer; and
a PFET differential spacer.

12. The system as claimed in claim 11 wherein:
the NFET differential spacer includes the NFET first liner and the NFET first spacer.

13. The system as claimed in claim 11 wherein:
the PFET differential spacer includes a PFET second liner and a PFET second spacer.

14. The system as claimed in claim 11 further comprising:
a PFET source/drain silicide contact aligned with a PFET second spacer of the PFET differential spacer.

15. The system as claimed in claim 11 wherein:
the NFET differential spacer is configured such that tensile stresses can be formed within an NFET channel; and
the PFET differential spacer is configured to prevent tensile stresses within a PFET channel.

16. The system as claimed in claim 11 further comprising:
an NFET source/drain silicide contact aligned to the NFET first spacer; and
a PFET source/drain silicide contact aligned to a PFET second spacer.

17. The system as claimed in claim 16 wherein:
the NFET source/drain silicide contact and the PFET source/drain silicide contact include materials selected from refractory metals.

18. The system as claimed in claim 11 wherein:
the punch-through suppression layer includes a silicon germanium layer.

19. The system as claimed in claim 11 further comprising:
the NFET first liner, the PFET first liner, and a PFET second liner made from materials that include oxygen.

20. The system as claimed in claim 11 further comprising:
the NFET first spacer, the PFET first spacer, and a PFET second spacer made from materials that include nitrogen.
